(19) United States
(12) Patent Application Publication
(10) Pub. No.: US 2006/0055415 A1
(43) Pub. Date: Mar. 16, 2006

(54) Environmentally compensated capacitive sensor

(76) Inventor: Mark Takita, Palo Alto, CA (US)

Correspondence Address: WHITHAM, CURTIS & CHRISTOFFERSON, P.C., 11491 SUNSET HILLS ROAD, SUITE 340, RESTON, VA, 20190, US

(21) Appl. No.: 10/940,929

(22) Filed: Sep. 15, 2004

(51) Int. Cl. G01R 27/26

(52) U.S. Cl. 324/658

(57) ABSTRACT

A capacitive sensor provides a high level of precision (potentially accurate within fractions of a nanometer) by taking the effects of environmental changes into consideration and compensating for any and all changes to the plate area and to the value of the dielectric constant before determining an accurate measurement. Such compensation can be achieved through use of a plurality of environmental sensors to mathematically calculate the change according to the variant conditions surrounding the capacitive sensor. Preferably, however, the compensation would be made through the use of a reference capacitor with a fixed gap between the plates but that is otherwise identical in both form and reaction to environmental changes as the capacitive sensor that it monitors in order to compensate for all environmental parameters other than the parameter of interest.

### BACKGROUND OF THE INVENTION

1. Field of the Invention

The present invention generally relates to capacitive sensors used for measuring small distances and small variations in distances, and, more particularly, to a capacitive distance sensor that is compensated for various changes in the environment including temperature, humidity, pressure, composition, or any of the constants used in the gases law, PV=NRT.

2. Description of the Prior Art

Higher precision is becoming increasingly required in a wide variety of endeavors including manufacturing processes. For example, as technology has advanced, microprocessor chips and transistors have notably decreased in size while increasing in functionality due to improvements in semi-conductor manufacturing technologies allowing increased integration density. In order to proceed in creating further generations of smaller and more efficient semi-conductors, a higher level of accuracy is becoming increasingly demanded.

A lithographic process is currently used as the preferred method for projecting patterns onto the silicon wafer in order to create a desired circuit. This process requires a source of light or radiation (e.g. an electron beam) to be directed through a series of accurately positioned lenses between which, a reticle containing the pattern to be projected is located. A wafer, coated with a radiation sensitive resist, is located on the opposite side of the lenses to receive the projected pattern. The pattern as projected onto the silicon wafer is often demagnified in proportion by the lenses. At the present state of the art, a total error budget (including abberation, astigmatation, and position is often as small as 0.5 nm at the wafer. Therefore, relative positions of various elements of the lithography tool which may be subject to slight changes due to environmental conditions must be continually monitored to maintain such a stringent tolerance.

The preferred method of measuring and monitoring these critical distances is often through the use of capacitive sensors. The desirability of capacitive sensors for this purpose is due to their ability to measure extremely small distances and variations thereof in a repeatably consistent and reliable fashion. Capacitive sensors, however, are subject to atmospheric changes (e.g. temperature, humidity, pressure, composition) that may have been negligible in the past but must be addressed in order to maintain smaller tolerances presently and foreseeably required.

The possible need for increased accuracy of measurement using capacitor sensors to maintain these tolerances, particularly in the presence of changes in environmental conditions, is discussed in U.S. Pat. No. 4,864,295, which increases sensitivity to measurement of shaft rotation by providing two pairs of capacitances which vary oppositely with shaft rotation and also provide substantial insensitivity to radial and axial shaft motion. Drift of the shaft rotation measurement with temperature is acknowledged but principally attributed to drift in the oscillator circuit which is used to derive measurement voltages from capacitors. This effect is compensated to a degree by use of an additional capacitor similarly subject to capacitance changes with temperature in a feedback circuit which stabilizes the voltage controlled oscillator. However, effects of other environmental parameters are not considered.

Nevertheless, it has been acceptable in many past applications for the change in capacitance to be viewed simply as a function of the change in the distance between the plates while the dielectric constant and the area of the plates are assumed to remain constant. However, in current high precision measurement devices for some applications such as lithography processes, assumptions that variables that undergo minute changes remain constant, as in the rotary motion as mentioned in U.S. Pat. No. 4,864,295, can no longer be tolerated. These minute changes are more critical and may occur over substantial distances or lengths of structure due to the effect of the atmospheric or environmental conditions on the area of the plate surfaces and on the consistency of the material between the two plates becomes enough so as to yield significant measurement error. Using the well-known equation C=(AK)/(4nd), the error created by treating the area [A] and dielectric constant [K] as fixed numbers instead of variables will cause a change in capacitance to be interpreted as a change in plate separation distance (d) being measured.

The problem of accounting for environmental factors in regard to capacitive sensors is also complicated by the fact that some environmental parameters are also commonly measured by capacitive sensors. Therefore, even indirect calibration or compensation of one capacitive sensor with another capacitive sensor as in U.S. Pat. No. 4,864,295 where a reference capacitor regulates a measurement oscillator has generally been impractical, complex and limited to less than all sources of error and direct compensation is effectively self-referential.

### SUMMARY OF THE INVENTION

The present invention provides compensation for the effects of environmental factors on capacitive sensors to reduce the error in the distance measurements monitored by the capacitive sensors.

In order to accomplish this and other meritorious effects of the invention, a method for compensating a measurement made by a capacitive sensor is provided including the steps of determining a capacitance of a capacitive sensor, sensing at least one environmental parameter other than temperature affecting the capacitance value of the capacitive sensor, and computing a compensation value corresponding to the environmental parameter for the capacitance of the capacitive sensor.

Additionally, an environmentally compensated sensor is provided comprising a capacitive sensor, a reference sensor for determining a plurality of environmental parameters, in the vicinity of the capacitive sensor, a dielectric material between the capacitive sensor and reference sensor, and a compensation element configured to compensate the capacitive sensor for the environmental parameters affecting capacitance measurements.

Further, an environmentally compensated sensor is provided comprising a capacitive sensor, at least one environmental sensor, a dielectric material separating the sensor plates of the capacitive sensor and each environmental sensor, and a compensation element configured to compensate the capacitive sensor for environmental parameters affecting capacitance measurements responsive to the environmental sensors.

### BRIEF DESCRIPTION OF THE DRAWINGS

The foregoing and other objects, aspects and advantages will be better understood from the following detailed description of a preferred embodiment of the invention with reference to the drawings, in which:

FIGS. 1A, 1B, and 1C illustrate in a cross-sectional view the potential effects of environmental factors on the area (FIG. 1B) and the dielectric (FIG. 1C) as compared to the area and dielectric of the capacitor when it is not under influence by any environmental factors and therefore where the plate area and dielectric constant are invariant (FIG. 1A).

FIG. 2 is an isometric view of a particular embodiment of the invention using a reference capacitor.

FIG. 3 is an isometric view of a particular embodiment of the invention using various environmental sensors.

### DETAILED DESCRIPTION OF A PREFERRED EMBODIMENT OF THE INVENTION

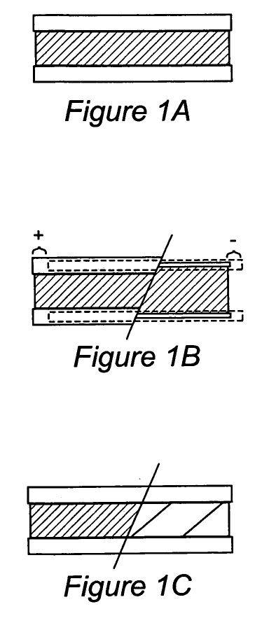

Referring now to the drawings, and more particularly to FIG. 1A, there is shown a cross-sectional view of a capacitive sensor uninfluenced by any environmental factors as though positioned within a vacuum. It should be appreciated that the effective capacitor dielectric is hatched in these views for purposes of clarity of illustration but it should be understood that the capacitor dielectric will normally be the ambient gas or fluid present between the plates. Fringing effects at the plate boundaries are omitted in the interest of clarity. The purpose of FIG. 1A when viewed in combination with either FIG. 1B or FIG. 1C is to illustrate the issue at hand regarding potential changes to the plate area and/or to the dielectric, respectively, when exposed to changing environmental factors. These examples, although exaggerated for presentation purposes, must be recognized as illustrating the separate effects of environmental factors on area (FIG. 1B) and dielectric (FIG. 1C) independently whereas, in actual practice the exposure to environmental factors will generally act upon these two capacitor elements in a variety of combinations and degrees depending on the particular structures and application and the type(s) and severity of change(s) occurring within the respective environmental parameters.

FIG. 1B illustrates how a plate material may expand or contract when faced with environmental changes (e.g. heating or cooling and, generally to a lesser degree, increasing or decreasing pressure) in comparison to FIG. 1A representing an identical capacitor system unaffected by environmental factors. Although the change in area may not, in practice, be observed by the naked eye, the action does in fact occur in accordance with the coefficient of thermal expansion and modulus of elasticity of the material of which the plates are formed. These small changes are of importance, particularly considering that the dimension changes occur in two orthogonal directions and the area change is the product of the altered dimensions while the sensed plate separation distance must often be accurate within less than 0.1 nm.

FIG. 1C illustrates the change in the makeup of the dielectric substance which may expand or contract based on a temperature or pressure change and thus may be altered in density producing a corresponding small change in dielectric constant and may also become mixed with different elements, particularly water vapor when considering a change in humidity and changes in gas composition due to reactions or outgassing due to altered temperature and/or pressure. For example, materials in proximity to the sensor plates may outgas certain molecular compounds. These compounds may re-deposit themselves on the sensor. Typically, materials such as metal and ceramic, exhibiting colder surfaces, bear a higher concentration of these deposits. Additionally, these sensor surfaces may also oxidize due to corrosion. As described in the consideration of determining an accurate measurement of area, the dielectric variable must also be accurately calculated so as to calculate the capacitance to a tolerance of small fractions of a Farad (e.g. pf). Therefore, all of the above factors must be taken into consideration.

According to information compiled by Earle C. Gregg, Jr. regarding the value of dielectric constants for various gases at a constant temperature and pressure (0° C. and 760 mm of Hg, respectively) the dielectric constant of air is 1.000590 while the dielectric constant of steam is 1.0126, a difference greater than 1%. If the original environmental conditions affecting the capacitive sensor happened to be the same conditions in which these two dielectric constants apply (air and steam at 0° C. and 760 mm) and do not change in any respect except for a change in humidity from 100% air to a mixture of 50% air and %50 steam, while all the plate area and capacitance stay the same, the capacitive sensor will not be able to correctly recognize the change in distance if it fails to recognize the change in the composition, and as a result, the value, of the dielectric constant. Although the change in distance that would occur as a result of increased humidity in this situation would be quite small, it could have critical ramifications to the high precision process in which it is part. In U.S. Pat. No. 4,864,295 that is cited as a prior art of this invention, it is noted that even while neglecting change in dielectric constant [K] within 0.10% of a variable value is not satisfactory for meeting the necessary functions of high precision measurement devices in some applications.

Likewise, as a controlled temperature and pressure were necessary for Gregg to compile his list of dielectric constants for gases, it is clear, as well as scientifically proven, that the dielectric of any medium (gas, liquid, or solid) will vary slightly as a function of temperature and/or pressure. With three environmental factors to consider (temperature, humidity/composition, and pressure) that are very difficult to precisely control outside of a vacuum environment (and, difficult even then) that are changing and effecting the value of the dielectric constant, there is no possible way of guaranteeing that a capacitive sensor without an environmentally compensating addition can meet the demands of precision that are becoming required of lithography and other processes.

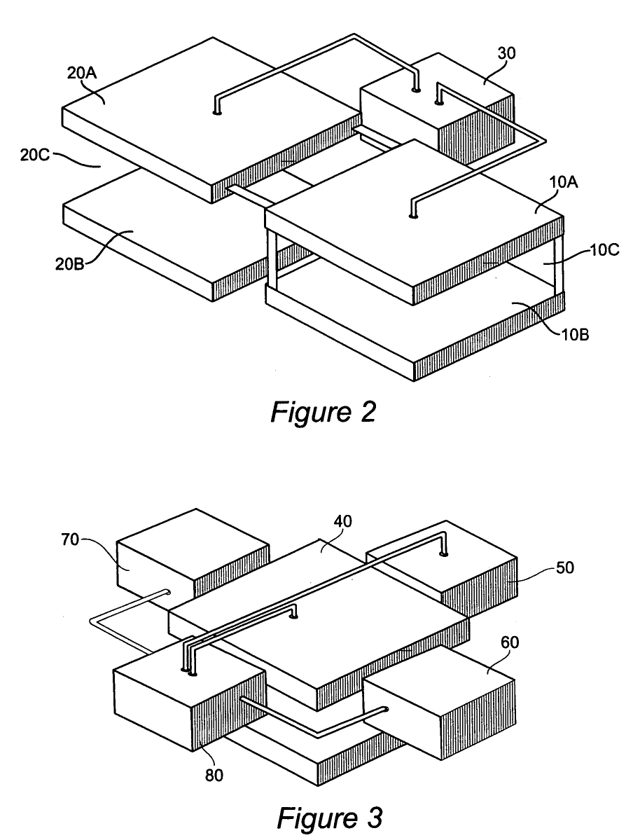

Referring now to FIG. 2, a preferred embodiment of the invention will be discussed. There is an isometric view of a reference capacitor 10 in close proximity a capacitive sensor 20. The reference capacitor is composed of two plates 10a and 10b of a fixed distance from one another and separated by a dielectric substance 10c. The capacitive sensor 20 is also comprised of two plates 20a and 20b separated by a dielectric substance 20c which are identical in composition to components 10a, 10b, and 10c of the reference capacitor 10. The only difference in construction that the capacitive sensor 20 exhibits when compared to the reference capacitor 10 is that the plates 20a and 20b are not set at a fixed distance from one another as dictated by the requirement of performing a measurement, and this distance is, in fact, expected to fluctuate with changes in relative position of parts of the apparatus to be monitored.

The close proximity of the two capacitors 10 and 20 ensures that they are being exposed to and acted upon by the same environmental factors and will consequently yield the same results in area change and dielectric constant. In such a situation, the formula for change of capacitance based on plate area, dielectric constant, and the distance between the plates shown as
ΔC=(ΔA×ΔK) (4π(Δd))
can be applied to both the reference capacitor 10 and the capacitive sensor 20 in order to identify the values of any unknown variables or to provide a lumped compensation value for all environmental parameters. However, the change in distance that the capacitive sensor is required to measure cannot be determined without prior knowledge of the product of the change in area and the change in dielectric value (ΔA×ΔK). The reference capacitor 10, however, using a fixed distance between plates, observes the change in capacitance (ΔC) solely as a function of the product of the change in area and the change in dielectric (ΔA×ΔK). The processor 30 can extract the value of (ΔA×ΔK) using the measurements of the reference capacitor and apply it to the capacitive sensor to accurately calculate the change of distance between plates 20a and 20b of capacitor 20. Therefore, all factors for consideration discussed above regarding sources of change for area and dielectric constant (e.g. temperature, humidity, pressure and their resulting effects, including possibly corrosion and/or outgassing) are inherently compensated.

It should be emphasized that this is the preferred configuration because of the simplicity and inherent accuracy of the calculation. If the reference capacitor and the capacitive sensor are identical in structure (with the one noted exception of a fixed distance on the reference capacitor) and located at such a close proximity to be experiencing and reacting to all environmental factors in and identical manner, then the changes are compensated for empathetically and the changes in the two variables ([A] and [K]) never need to be numerically identified. It is possible to achieve the same results through use of a non-identical but scaled pair (including capacitance sensor and reference capacitor), however, this is not the preferred configuration.

Referring now to FIG. 3, a more generalized embodiment of the invention will be explained. There is an isometric view of a capacitive sensor 40 (including two plates separated by a dielectric substance) in close proximity to various environmental sensors designed to calculate any changes in temperature 50, pressure 60, or humidity/composition 70 that take place within the direct environment of the capacitive sensor. Sensors used for such purposes are preferably of other than capacitive types (e.g. fiber optics) which may be inherently compensated for one or more environmental parameters. The separate changes in environmental factors observed from each of the sensors will be calculated mathematically within the processor 80 in combination with the other environmental factors as well as with the known behaviors of the materials or substances present in the sensor plates and in the dielectric substance. This information calculated by the processor will satisfy the value of the product of the change in area and the change in dielectric (ΔA×ΔK) in order to then determine the change in distance (Δd) based solely on the change in capacitance (AC).

In view of the foregoing, this invention provides accurate compensation for the effects of environmental factors on capacitive sensors to greatly reduce and ideally eliminate measurement errors in high precision applications. In so doing, the lithography process and others can achieve greater accuracy in their specific applications.

While the invention has been described in terms of a single preferred embodiment, those skilled in the art will recognize that the invention can be practiced with modification within the spirit and scope of the appended claims.

Having thus described my invention, what i claim as new and desire to secure by Letters Patent is as follows:

1. An environmentally compensated sensor comprising
a capacitive sensor,
a reference sensor for determining at least one environmental parameter, other than temperature, in the vicinity of said capacitive sensor, said environmental parameter affecting said capacitive sensor,
a dielectric material between said capacitive sensor and reference sensor, and
a compensation element configured to compensate said capacitive sensor for environmental parameters affecting capacitance measurements.

2. The environmentally compensated sensor as recited in claim 1, wherein said environmental parameters affecting said capacitive sensor include at least temperature, pressure, humidity and the resulting composition of a dielectric material of said capacitive sensor.

3. An apparatus as recited in claim 2, wherein said reference sensor includes capacitive plates, said capacitive plates of the reference sensor being a fixed distance apart.

4. An apparatus as recited in claim 3, wherein a compensation element uses the effects on the reference sensor due to changing environmental parameters in order to compensate for said environmental parameters and resulting effects on the capacitive sensor.

5. An environmentally compensated sensor comprising
a capacitive sensor,
at least one environmental sensor,
a dielectric material separating the sensor plates of the capacitive sensor and each said environmental sensor, and
a compensation element configured to compensate said capacitive sensor for environmental parameters affecting capacitance measurements responsive to said environmental sensors.

6. An apparatus as recited in claim 5 in which said at least one environmental sensor monitors change in humidity and/or pressure.

7. An apparatus as recited in claim 6 in which at least one additional environmental sensor monitors change in temperature.

8. A method for compensating a measurement made by a capacitive sensor including steps of
determining a capacitance of a capacitive sensor,
sensing at least one environmental parameter other than temperature affecting said capacitance value of said capacitive sensor, and
computing a compensation value corresponding to said environmental parameter for said capacitance of said capacitive sensor.

9. A method as recited in claim 8 in which said at least one environmental parameter measured by at least one environmental sensor is humidity or pressure.

10. A method as recited in claim 9 in which an additional environmental parameter measured is temperature.

11. A method as in claim 8 in which all environmental factors affecting capacitive sensor, including at least humidity, pressure and temperature, are compensated by reference sensor.
